(19) United States
(12) Patent Application Publication
(10) Pub. No.: US 2025/0287585 A1
(43) Pub. Date: Sep. 11, 2025

(54) MANUFACTURING METHOD OF SEMICONDUCTOR STRUCTURE

(71) Applicant: Winbond Electronics Corp., Taichung City (TW)

(72) Inventors: Yao-Ting Tsai, Taichung City (TW); Yu-Jen Huang, Taichung City (TW); Hsiu-Han Liao, Hsiuchu (TW)

(73) Assignee: Winbond Electronics Corp., Taichung City (TW)

(21) Appl. No.: 18/613,139

(22) Filed: Mar. 22, 2024

(30) Foreign Application Priority Data
Mar. 5, 2024 (TW) 113107851

(51) Int. Cl. H10B 41/42; H01L 21/311; H01L 21/762; H01L 29/66

(52) U.S. Cl. CPC H10B 41/42; H01L 21/31116; H01L 21/31144; H01L 21/76224; H10D 30/0411; H10D 64/015

(57) ABSTRACT

A manufacturing method of a semiconductor structure including the following steps is provided. A substrate is provided. The substrate includes a peripheral region and a memory region. A first isolation structure is formed in the substrate in the peripheral region. After the first isolation structure is formed, a first floating gate layer and a tunneling dielectric layer are formed in the memory region. The first floating gate layer is located on the substrate. The tunneling dielectric layer is located between the first floating gate layer and the substrate. After the first floating gate layer and the tunneling dielectric layer are formed, a second isolation structure is formed in the substrate in the memory region.

### CROSS-REFERENCE TO RELATED APPLICATION

This application claims the priority benefit of Taiwan application serial no. 113107851, filed on Mar. 5, 2024. The entirety of the above-mentioned patent application is hereby incorporated by reference herein and made a part of this specification.

### BACKGROUND

### Technical Field

The invention relates to a manufacturing method of a semiconductor structure, and particularly relates to a manufacturing method of a semiconductor structure including a floating gate layer and a tunneling dielectric layer.

### Description of Related Art

Since the non-volatile memory has the advantage that the stored data will not disappear even after being powered off, many electronic products must require this type of memory to maintain normal operation when the electronic products are turned on. However, how to improve the reliability and the operation speed of the memory device is the goal of continuous efforts.

### SUMMARY

The invention provides a manufacturing method of a semiconductor structure, which can improve the reliability and the operation speed of the memory device.

The invention provides a manufacturing method of a semiconductor structure, which includes the following steps. A substrate is provided. The substrate includes a peripheral region and a memory region. A first isolation structure is formed in the substrate in the peripheral region. After the first isolation structure is formed, a first floating gate layer and a tunneling dielectric layer are formed in the memory region. The first floating gate layer is located on the substrate. The tunneling dielectric layer is located between the first floating gate layer and the substrate. After the first floating gate layer and the tunneling dielectric layer are formed, a second isolation structure is formed in the substrate in the memory region.

Based on the above description, in the manufacturing method of the semiconductor structure according to the invention, before the second isolation structure is formed in the substrate in the memory region, the first floating gate layer and the tunneling dielectric layer are formed in the memory region. Therefore, the corner thinning of the tunneling dielectric layer can be prevented, so that the tunneling dielectric layer can have a uniform thickness, thereby improving the reliability of the memory device. In addition, the thickness of the tunneling dielectric layer can be adjusted according to requirements, thereby improving the operation speed of the memory device.

### BRIEF DESCRIPTION OF THE DRAWINGS

FIG. 1A to FIG. 1U are cross-sectional views of a manufacturing process of a semiconductor structure according to some embodiments of the invention.

### DESCRIPTION OF THE EMBODIMENTS

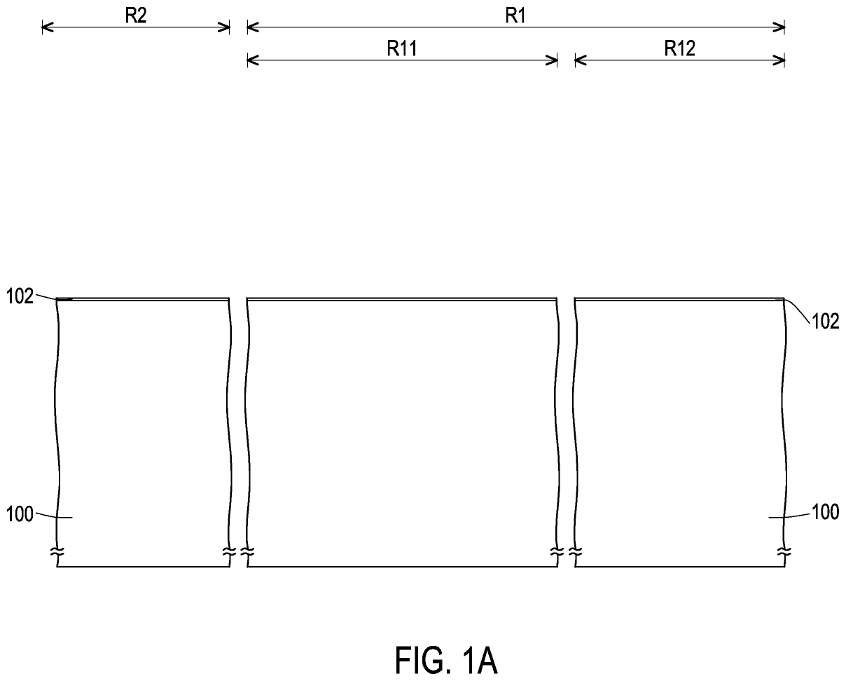

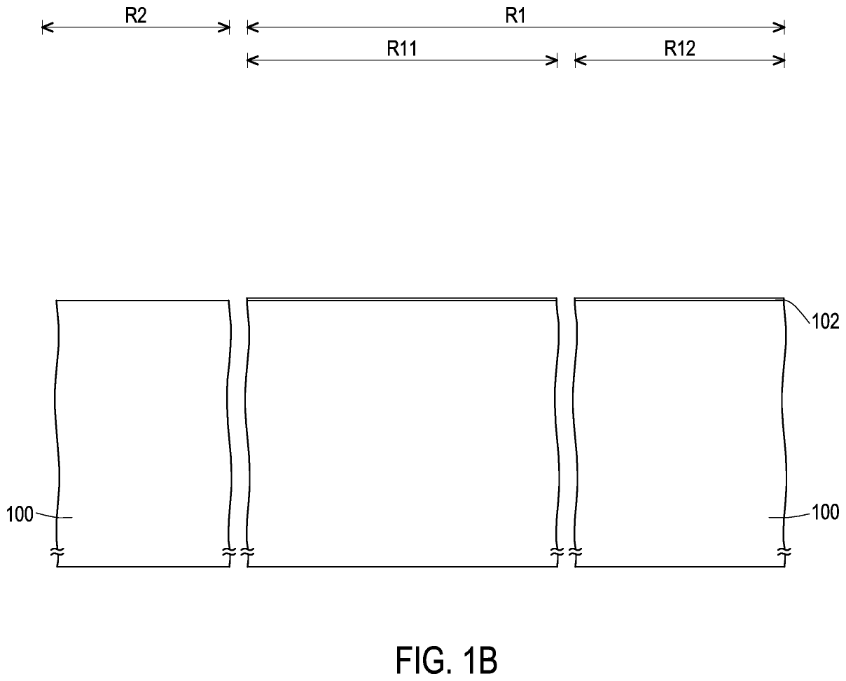

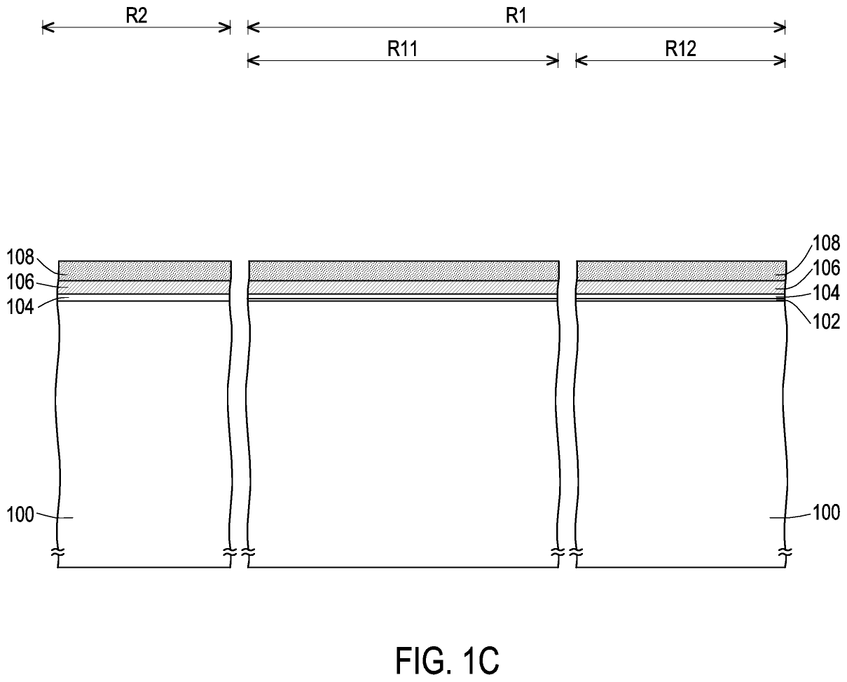

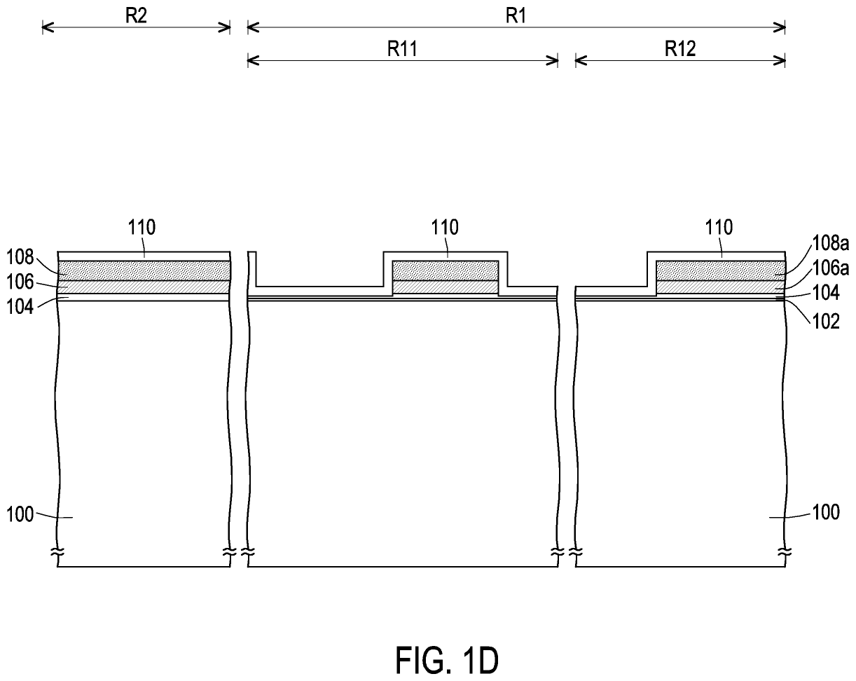

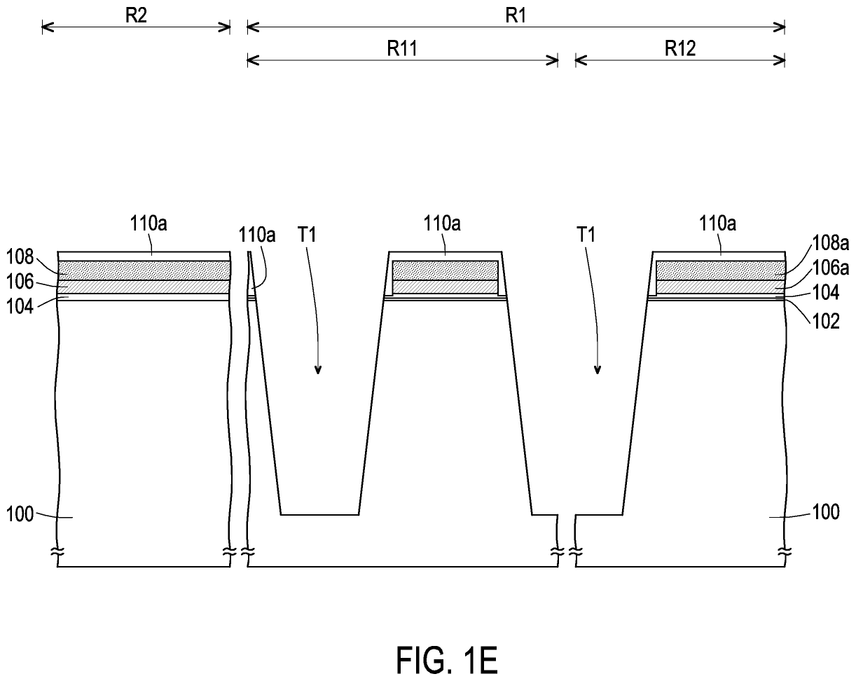

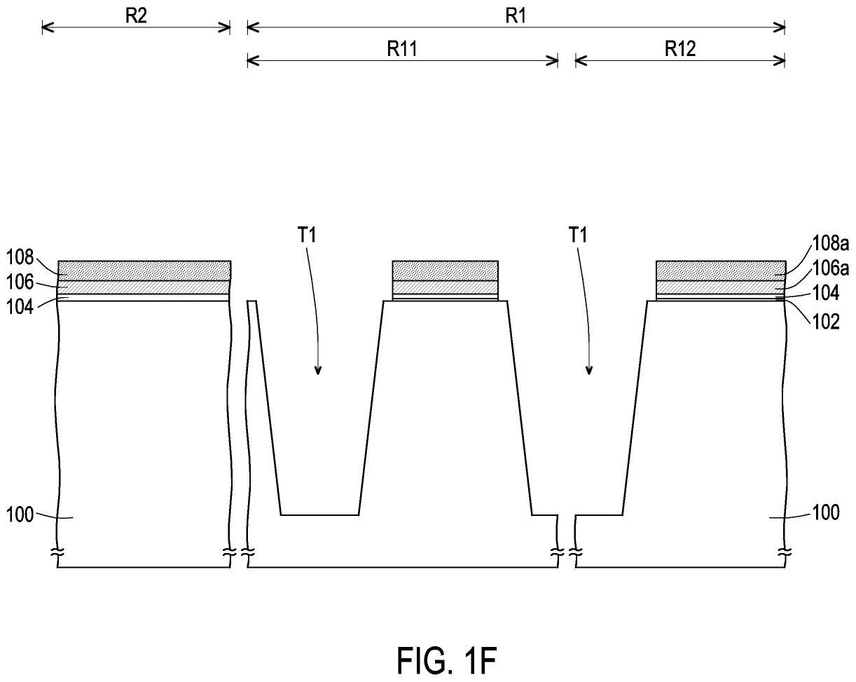

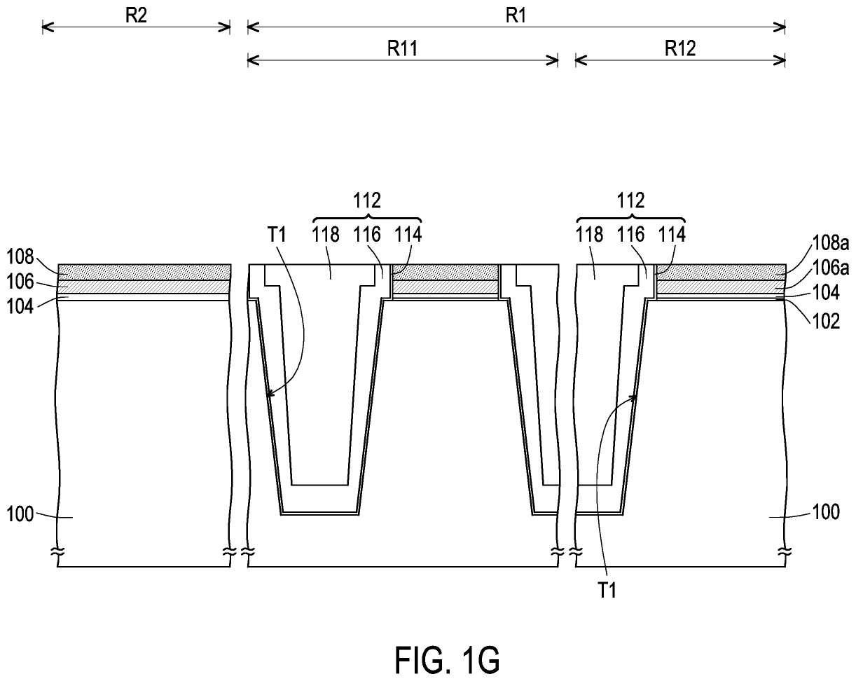

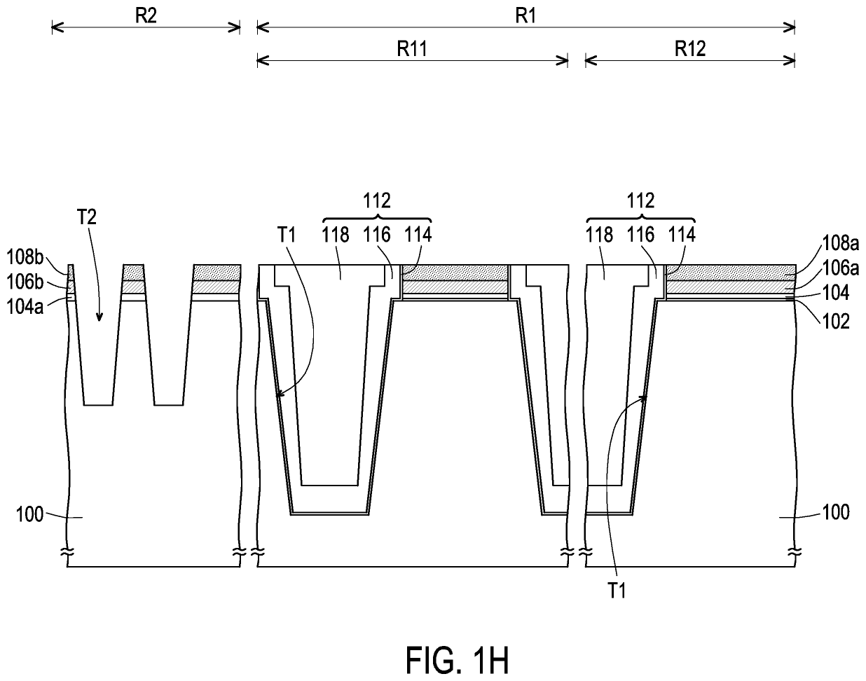

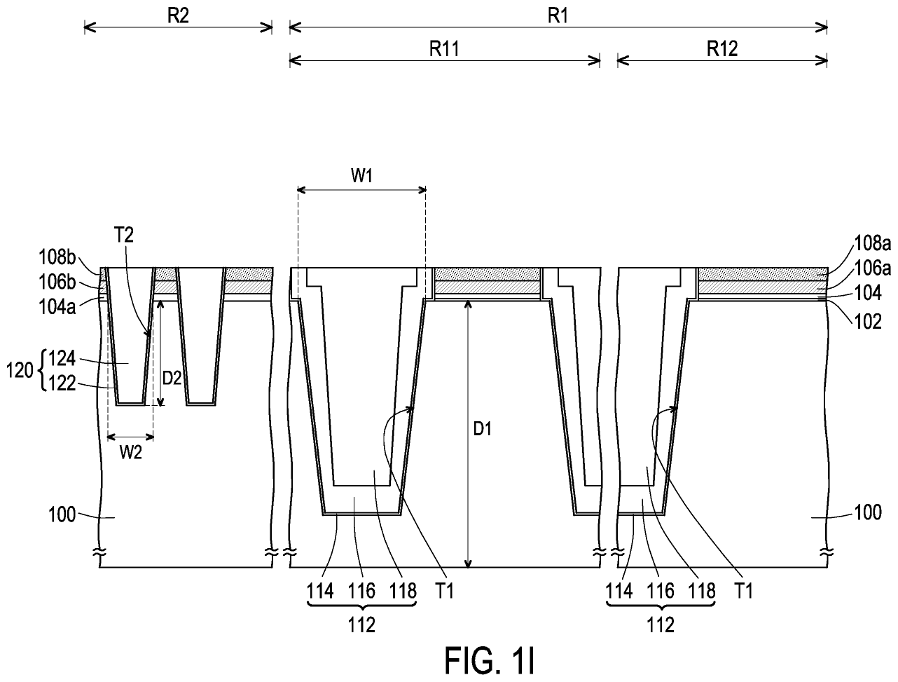

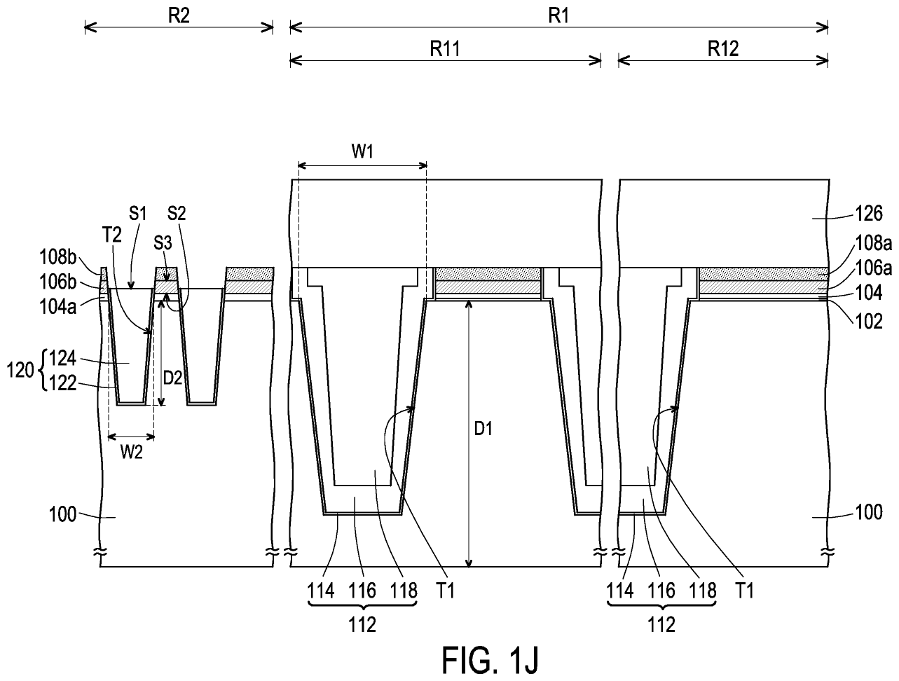

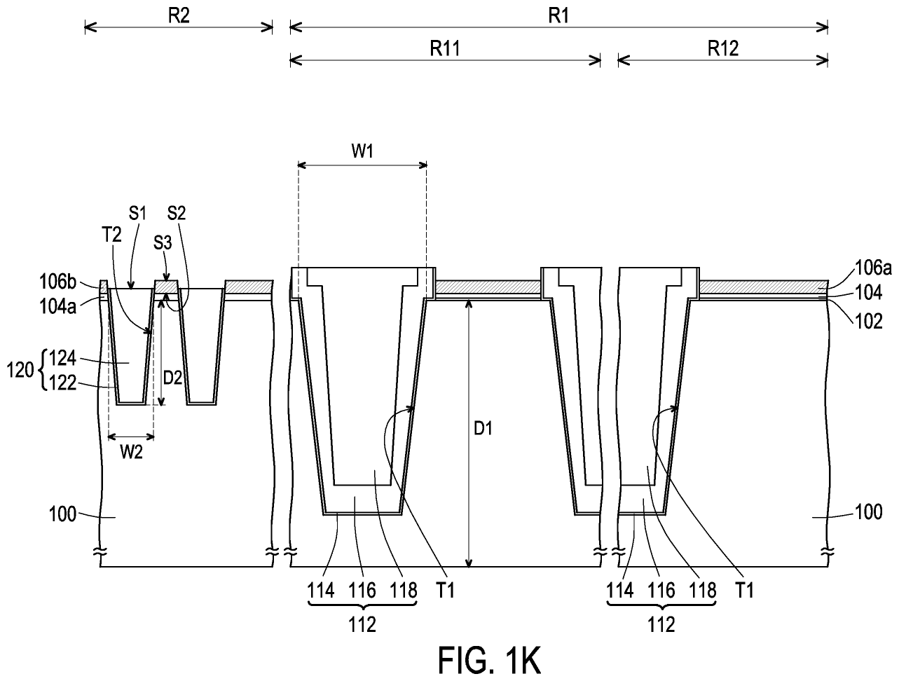

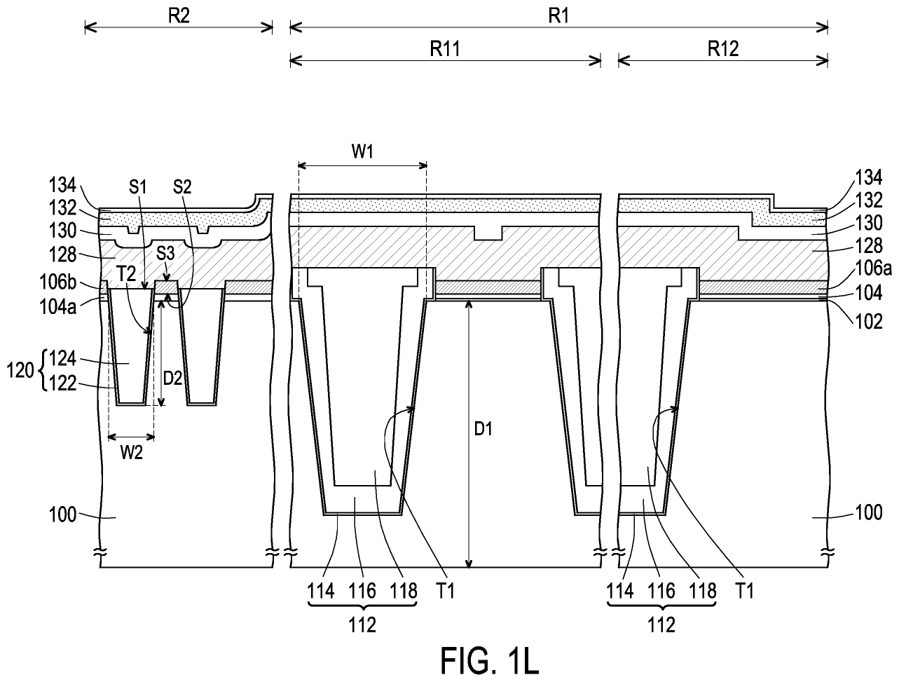

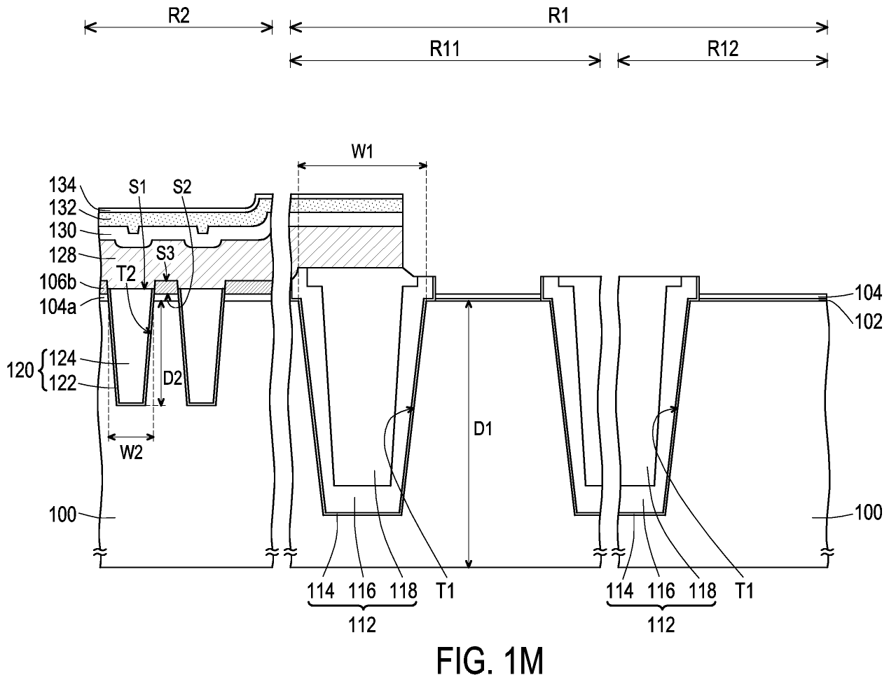

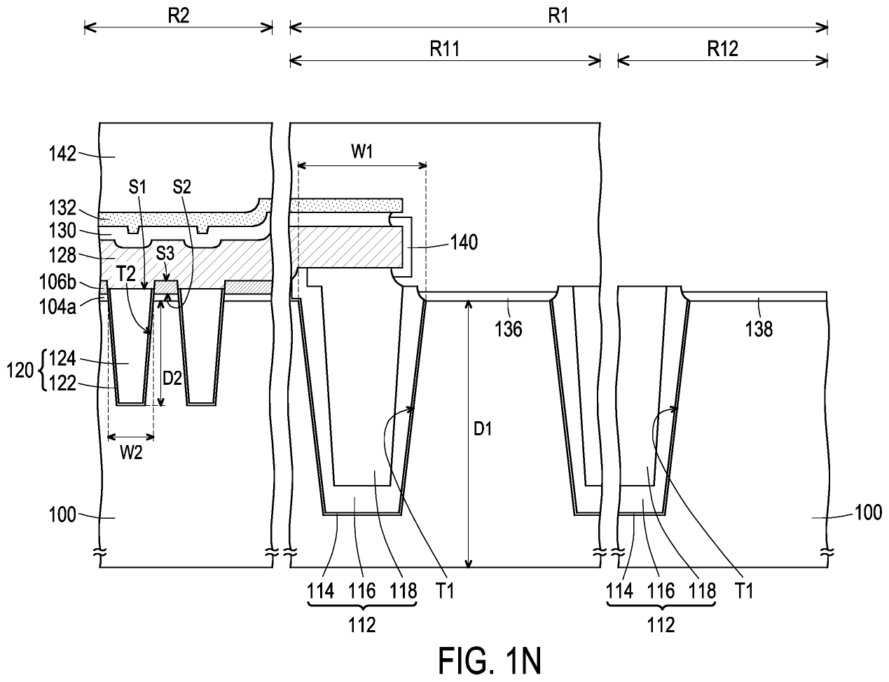

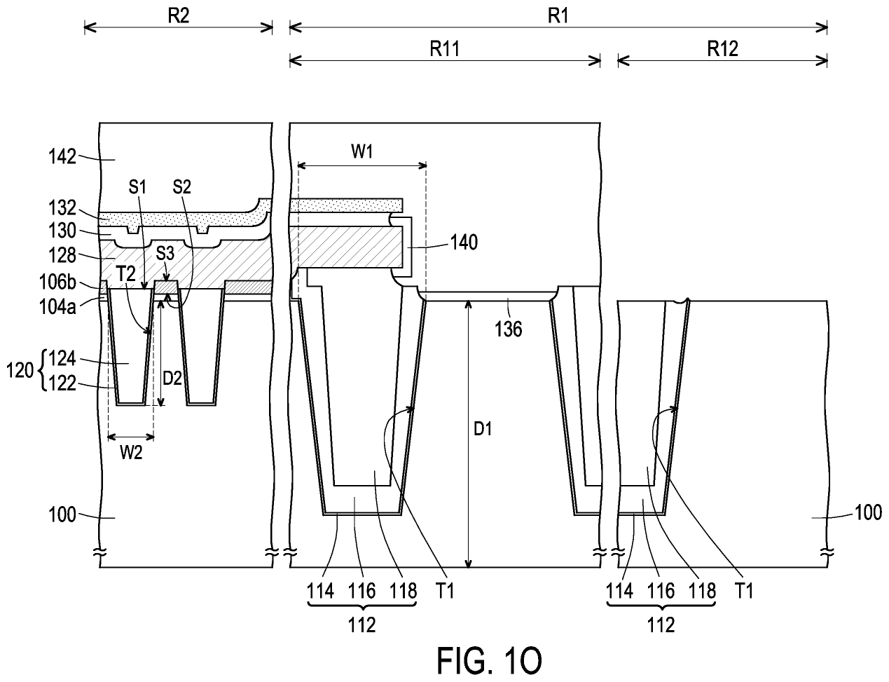

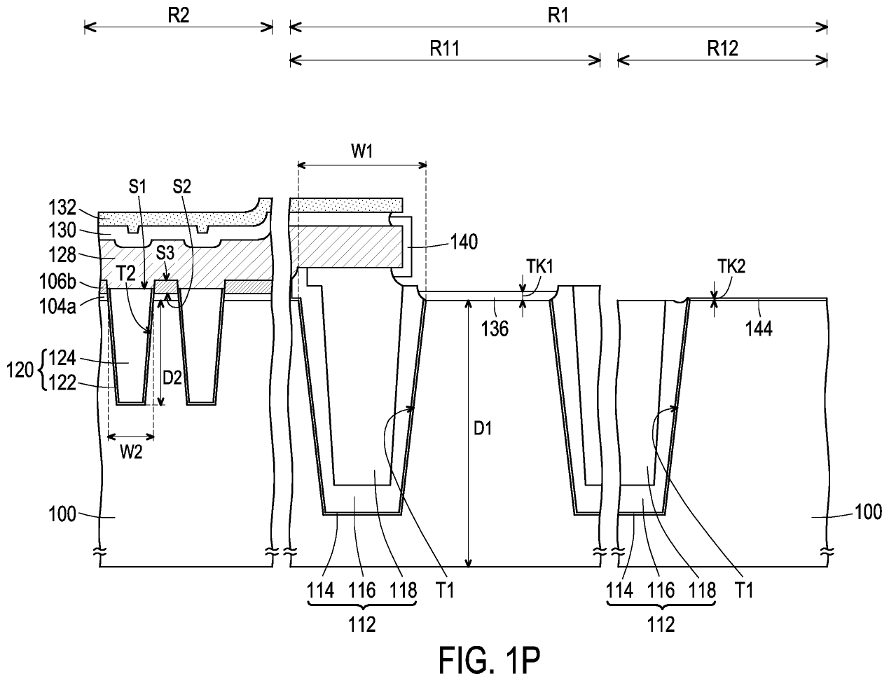

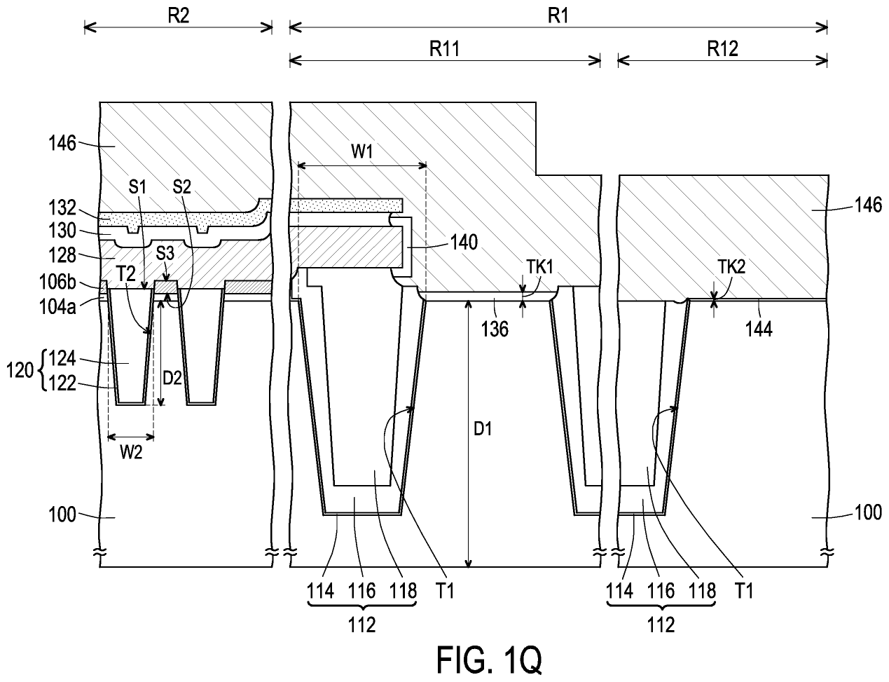

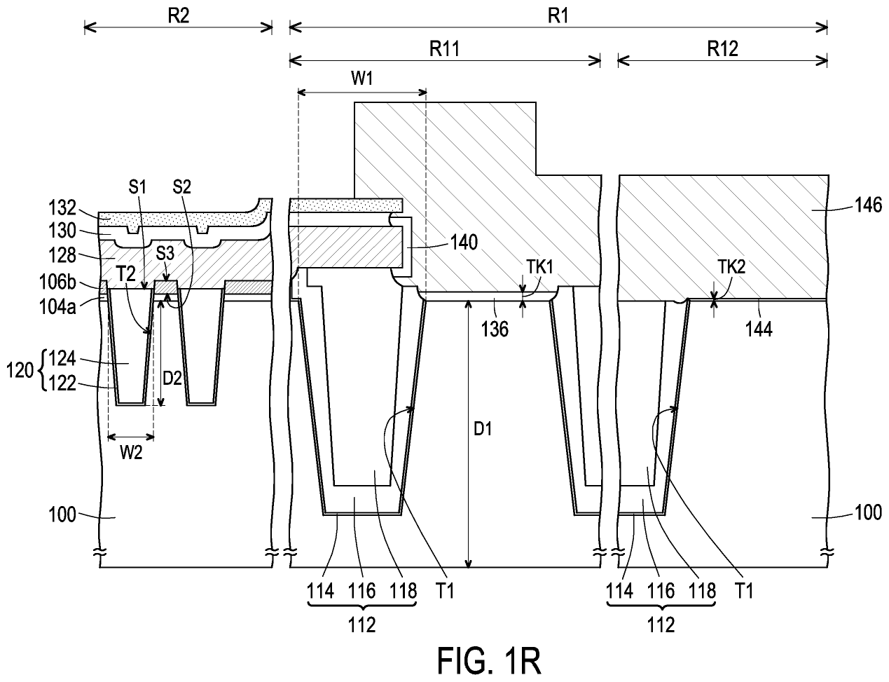

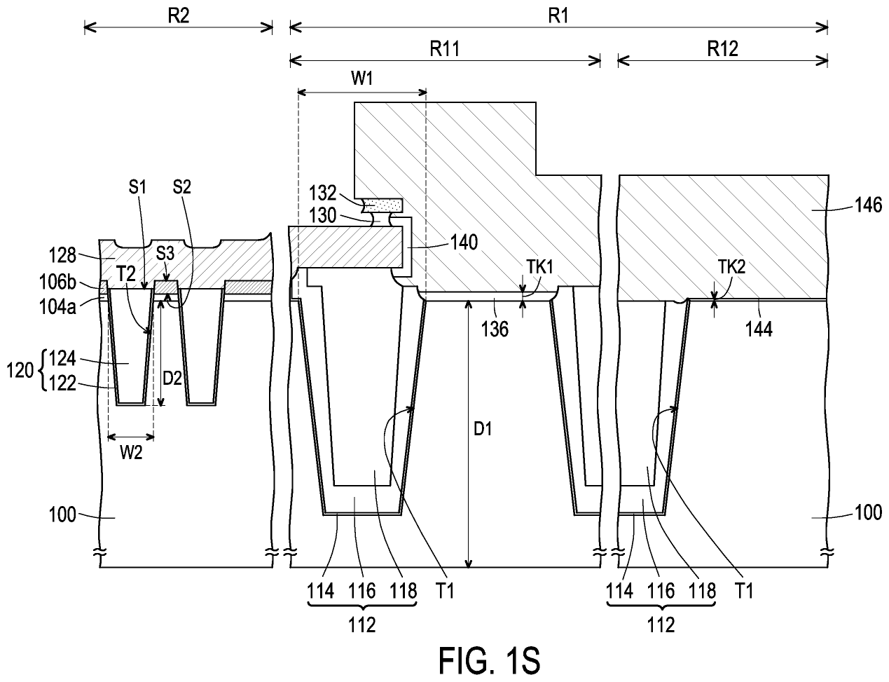

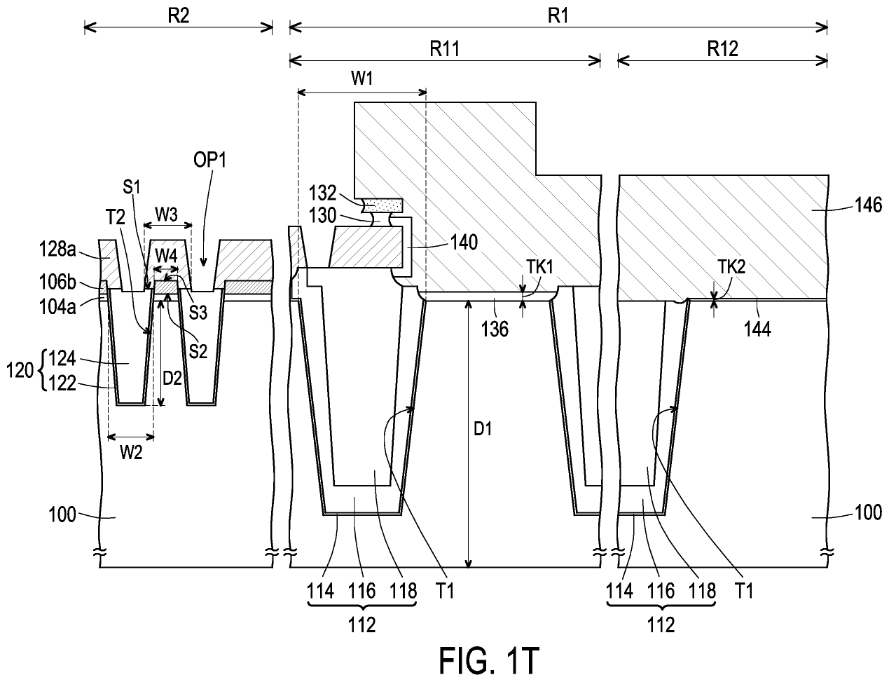

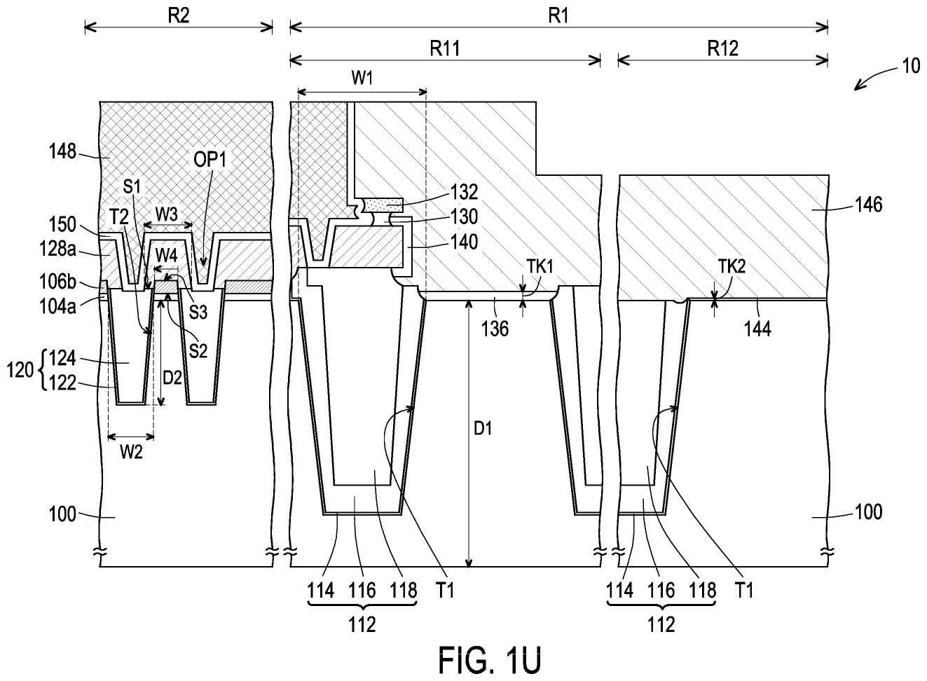

Referring to FIG. 1A, a substrate 100 is provided. The substrate 100 includes a peripheral region R1 and a memory region R2. The peripheral region R1 may be a peripheral circuit region. The peripheral region R1 may include a first region R11 and a second region R12. In some embodiments, the first region R11 may be a high-voltage device region (e.g., high-voltage transistor region), and the second region R12 may be a low-voltage device region (e.g., low-voltage transistor region). The memory region R2 may be a flash memory region such as a NOR flash memory region. The substrate 100 may be a semiconductor substrate such as a silicon substrate.

A pad layer 102 may be formed on the substrate 100. The material of the pad layer 102 may include silicon oxide. The method of forming the pad layer 102 may include a thermal oxidation method. Required doped regions (e.g., well region) (not shown) may be formed in the substrate 100 in the memory region R2.

Referring to FIG. 1B, the pad layer 102 in memory region R2 may be removed. In some embodiments, the pad layer 102 in the memory region R2 may be removed by a lithography process and an etching process.

Referring to FIG. 1C, a dielectric material layer 104, a floating gate material layer 106, and a hard mask layer 108 may be sequentially formed on the substrate 100. The dielectric material layer 104 in the peripheral region R1 may be located on the pad layer 102. The material of the dielectric material layer 104 may include silicon oxide. The method of forming the dielectric material layer 104 may include a thermal oxidation method. The material of the floating gate material layer 106 may include undoped polysilicon or doped polysilicon. The method of forming the floating gate material layer 106 may include a chemical vapor deposition (CVD) method. The material of the hard mask layer 108 may include silicon nitride. The method of forming the hard mask layer 108 may include a CVD method.

Referring to FIG. 1D, the hard mask layer 108 and the floating gate material layer 106 in the peripheral region R1 are patterned to form a patterned hard mask layer 108a and a patterned floating gate material layer 106a in the peripheral region R1. In some embodiments, the hard mask layer 108 and the floating gate material layer 106 in the peripheral region R1 may be patterned by a lithography process and an etching process.

A spacer material layer 110 may be conformally formed on the patterned hard mask layer 108a, the patterned floating gate material layer 106a, the dielectric material layer 104, and the hard mask layer 108. The method of forming the spacer material layer 110 may include an atomic layer deposition method.

Referring to FIG. 1E, the spacer material layer 110, the dielectric material layer 104, the pad layer 102, and the substrate 100 may be patterned to form a spacer 110a and to form a trench T1 in the substrate 100. The spacer 110a is located on the sidewall and the top surface of the patterned hard mask layer 108a and is located on the sidewall of the patterned floating gate material layer 106a. The spacer 110a may be further located on the dielectric material layer 104. In some embodiments, the spacer material layer 110, the dielectric material layer 104, the pad layer 102, and the substrate 100 may be patterned by a lithography process and an etching process.

Referring to FIG. 1F, the spacer 110a may be removed. In the process of removing the spacer 110a, a portion of the dielectric material layer 104 and a portion of the pad layer 102 located directly below the spacer 110a may be simultaneously removed. The method of removing the spacer 110a may include a wet etching method.

Referring to FIG. 1G, an isolation structure 112 may be formed in the trench T1. Therefore, the isolation structure 112 may be formed in the substrate 100 in the peripheral region R1. The isolation structure 112 may be located on the sidewall of the patterned hard mask layer 108a and the sidewall of the patterned floating gate material layer 106a. The isolation structure 112 may be a single-layer structure or a multilayer structure. In the present embodiment, the isolation structure 112 is, for example, a multilayer structure. For example, the isolation structure 112 may include a liner layer 114, a dielectric layer 116, and a dielectric layer 118. The liner layer 114, the dielectric layer 116, and the dielectric layer 118 are sequentially located in the trench T1. The material of the liner layer 114 may include silicon oxide formed by a CVD process. The material of the dielectric layer 116 may include silicon oxide formed by a high aspect ratio process (HARP). The material of the dielectric layer 118 may include silicon oxide formed by a CVD process. In some embodiments, the method of forming the liner layer 114, the dielectric layer 116, and the dielectric layer 118 may include the following steps. First, the material layer of the liner layer 114, the material layer of the dielectric layer 116, and the material layer of the dielectric layer 118 filling the trench T1 may be sequentially formed. Then, a chemical mechanical polishing (CMP) process may be performed on the material layer of the dielectric layer 118, the material layer of the dielectric layer 116, and the material layer of the liner layer 114 to form the dielectric layer 118, the dielectric layer 116, and the liner layer 114.

Referring to FIG. 1H, the hard mask layer 108, the floating gate material layer 106, and the dielectric material layer 104 in the memory region R2 may be patterned to form a patterned hard mask layer 108b, a floating gate layer 106b, and a tunneling dielectric layer 104a. Therefore, after the isolation structure 112 is formed, the floating gate layer 106b and the tunneling dielectric layer 104a may be formed in the memory region R2. The floating gate layer 106b is located on the substrate 100. The tunneling dielectric layer 104a is located between the floating gate layer 106b and the substrate 100. In addition, the substrate 100 in the memory region R2 may be patterned to form a trench T2 in the substrate 100. In some embodiments, the hard mask layer 108, the floating gate material layer 106, the dielectric material layer 104, and the substrate 100 in the memory region R2 may be patterned by a lithography process and an etching process.

Referring to FIG. 1I, an isolation structure 120 may be formed in the trench T2. Therefore, after the floating gate layer 106b and the tunneling dielectric layer 104a are formed, the isolation structure 120 may be formed in the substrate 100 in the memory region R2. The depth D1 of the isolation structure 112 located in the substrate 100 may be greater than the depth D2 of the isolation structure 120 located in the substrate 100. The width W1 of the isolation structure 112 located in the substrate 100 may be greater than the width W2 of the isolation structure 120 located in the substrate 100. The isolation structure 120 may be a single-layer structure or a multilayer structure. In the present embodiment, the isolation structure 120 is, for example, a multilayer structure. For example, the isolation structure 120 may include a liner layer 122 and a dielectric layer 124. The liner layer 122 and the dielectric layer 124 are sequentially located the in the trench T2. The material of the liner layer 122 may include silicon oxide formed by a CVD process. The material of the dielectric layer 124 may include silicon oxide formed by a high aspect ratio process (HARP). In some embodiments, a method of forming the liner layer 122 and the dielectric layer 124 may include the following steps. First, the material layer of the liner layer 122 and the material layer of the dielectric layer 124 filling the trench T2 may be sequentially formed. Then, a CMP process may be performed on the material layer of the dielectric layer 124 and the material layer of the liner layer 122 to form the dielectric layer 124 and the liner layer 122.

Referring to FIG. 1J, a patterned photoresist layer 126 may be formed in the peripheral region R1. The patterned photoresist layer 126 may cover the isolation structure 112. The patterned photoresist layer 126 may further cover the patterned hard mask layer 108a. The patterned photoresist layer 126 may be formed by a lithography process.

An etch back process (e.g., dry etching process) may be performed on the isolation structure 120 by using the patterned photoresist layer 126 as a mask to reduce the height of the isolation structure 120. The isolation structure 120 may be located on the sidewall of the tunneling dielectric layer 104a and the sidewall of the floating gate layer 106b. The top surface S1 of the isolation structure 120 may be higher than the bottom surface S2 of the floating gate layer 106b and lower than the top surface S3 of the floating gate layer 106b.

Referring to FIG. 1K, the patterned photoresist layer 126 may be removed. The method of removing the patterned photoresist layer 126 may include a dry stripping method or a wet stripping method.

The patterned hard mask layers 108a and 108b may be removed. The method of removing the patterned hard mask layers 108a and 108b may include a wet etching method.

Referring to FIG. 1L, a floating gate material layer 128 may be formed on the floating gate layer 106b. The floating gate material layer 128 may be further formed on the isolation structure 120, the isolation structure 112, and the patterned floating gate material layer 106a. The material of the floating gate material layer 128 may include undoped polysilicon or doped polysilicon. The method of forming the floating gate material layer 128 may include a CVD method.

A hard mask layer 130, a hard mask layer 132, and a hard mask layer 134 may be sequentially formed on the floating gate material layer 128. The materials of the hard mask layers 130 and 134 may include silicon oxide. The material of the hard mask layer 132 may include silicon nitride. The method of forming hard mask layers 130, 132, and 134 may include a CVD method.

Referring to FIG. 1M, a portion of the hard mask layer 134, a portion of the hard mask layer 132, a portion of the hard mask layer 130, a portion of the floating gate material layer 128, and the patterned floating gate material layer 106a in the peripheral region R1 may be removed. In some embodiments, a portion of the hard mask layer 134, a portion of the hard mask layer 132, a portion of the hard mask layer 130, a portion of the floating gate material layer 128, and the patterned floating gate material layer 106a in the peripheral region R1 may be removed by a lithography process and an etching process. In the above etching process, a portion of the isolation structure 112 may be removed. Required doped regions (e.g., well region) (not shown) may be formed in the substrate 100 in the peripheral region R1.

Referring to FIG. 1N, the dielectric material layer 104 and the pad layer 102 in the peripheral region R1 may be removed. The method of removing the dielectric material layer 104 and the pad layer 102 in the peripheral region R1 may include a wet etching method. In the process of removing the dielectric material layer 104 and the pad layer 102 in the peripheral region R1, the hard mask layer 134, a portion of the hard mask layer 130, and a portion of the isolation structure 112 may be removed.

A gate dielectric layer 136 and a gate dielectric layer 138 may be formed on the substrate 100 in the peripheral region R1. The gate dielectric layer 136 and the gate dielectric layer 138 may be respectively located in the first region R11 and the second region R12. In the process of forming the gate dielectric layer 136 and the gate dielectric layer 138, a dielectric layer 140 may be simultaneously formed on the floating gate material layer 128. The materials of the gate dielectric layer 136, the gate dielectric layer 138, and the dielectric layer 140 may include silicon oxide. The method of forming the gate dielectric layer 136, the gate dielectric layer 138, and the dielectric layer 140 may include a thermal oxidation method.

A patterned photoresist layer 142 may be formed in the memory region R2 and the first region R11. The patterned photoresist layer 142 may expose the gate dielectric layer 138 and a portion of the isolation structure 112 in the second region R12. The patterned photoresist layer 142 may be formed by a lithography process.

Referring to FIG. 1O, the dielectric layer 138 may be removed by using the patterned photoresist layer 142 as a mask. In the process of removing the gate dielectric layer 138, a portion of the isolation structure 112 exposed by the patterned photoresist layer 142 may be removed. In some embodiments, the method of removing the gate dielectric layer 138 and a portion of the isolation structure 112 may include a wet etching method.

Referring to FIG. 1P, the patterned photoresist layer 142 may be removed. The method of removing the patterned photoresist layer 142 may include a dry stripping method or a wet stripping method.

A gate dielectric layer 144 may be formed on the substrate 100 in the peripheral region R1 (e.g., second region R12). The gate dielectric layer 136 and the gate dielectric layer 144 may be separated from each other. The thickness TK1 of the gate dielectric layer 136 may be greater than the thickness TK2 of the gate dielectric layer 144. The method of forming the gate dielectric layer 144 may include a thermal oxidation method.

Referring to FIG. 1Q, a gate material layer 146 may be formed on the gate dielectric layer 136 and the gate dielectric layer 144. The gate material layer 146 may be further formed on the hard mask layer 132 in the memory region R2. The material of gate material layer 146 may include doped polysilicon. The method of forming the gate material layer 146 may include a CVD method.

Referring to FIG. 1R, the gate material layer 146 in the memory region R2 may be removed to expose the hard mask layer 132. In some embodiments, the gate material layer 146 in the memory region R2 may be removed by a lithography process and an etching process.

Referring to FIG. 1S, the hard mask layer 132 in the memory region R2 may be removed. The method of removing the hard mask layer 132 in the memory region R2 may include a wet etching method. The hard mask layer 130 in memory region R2 may be removed. The method of removing the hard mask layer 130 in the memory region R2 may include a wet etching method. In some embodiments, a portion of the hard mask layer 132 and a portion of the hard mask layer 130 may remain directly above the isolation structure 112 located at the edge of the first region R11.

Referring to FIG. 1T, the floating gate material layer 128 may be patterned to form a floating gate layer 128a and an opening OP1. Therefore, the floating gate layer 128a may be formed on the floating gate layer 106b. A portion of the floating gate layer 128a may be located on the isolation structure 120. The width W3 of the floating gate layer 128a may be greater than the width W4 of the floating gate layer 106b. In some embodiments, the floating gate material layer 128 may be patterned by a lithography process and an etching process. In some embodiments, the etching process may be a dry etching process, thereby forming the opening OP1 with the required specification. In this way, it helps to improve the process window of the subsequent process of forming a control gate 148 (FIG. 1U) in the opening OP1.

Referring to FIG. 1U, a control gate 148 may be formed on the floating gate layer 128a and in the opening OP1. The material of the control gate 148 may include doped polysilicon. In addition, a dielectric layer 150 may be formed between the control gate 148 and the floating gate layer 128a. The dielectric layer 150 may be a single-layer structure or a multilayer structure. In some embodiments, the dielectric layer 150 may be an oxide/nitride/oxide (ONO) composite layer.

In subsequent processes, the gate material layer 146 may be patterned to respectively form a gate for a high-voltage device (e.g., high-voltage transistor device) and a gate for a low-voltage device (e.g., low-voltage transistor device) in the first region R1 and the second region R2, respectively, and the description thereof is omitted here.

Based on the above embodiments, in the manufacturing method of the semiconductor structure 10, before the isolation structure 120 is formed in the substrate 100 in the memory region R2, the floating gate layer 106b and the tunneling dielectric layer 104a are formed in the memory region R2. Therefore, the corner thinning of the tunneling dielectric layer 104a can be prevented, so that the tunneling dielectric layer 104a can have a uniform thickness, thereby improving the reliability of the memory device (e.g., NOR flash memory). In addition, the thickness of the tunneling dielectric layer 104a can be adjusted according to requirements, thereby improving the operation speed of the memory device (e.g., NOR flash memory device).

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A manufacturing method of a semiconductor structure, comprising:
providing a substrate, wherein the substrate comprises a peripheral region and a memory region;
forming a first isolation structure in the substrate in the peripheral region;
after forming the first isolation structure, forming a first floating gate layer and a tunneling dielectric layer in the memory region, wherein the first floating gate layer is located on the substrate, and the tunneling dielectric layer is located between the first floating gate layer and the substrate; and
after forming the first floating gate layer and the tunneling dielectric layer, forming a second isolation structure in the substrate in the memory region.

2. The manufacturing method of the semiconductor structure according to claim 1, wherein a method of forming the first isolation structure comprises:
sequentially forming a dielectric material layer, a floating gate material layer, and a hard mask layer on the substrate;
patterning the hard mask layer and the floating gate material layer in the peripheral region to form a patterned hard mask layer and a patterned floating gate material layer in the peripheral region;
conformally forming a spacer material layer on the patterned hard mask layer, the patterned floating gate material layer, and the dielectric material layer;
patterning the spacer material layer, the dielectric material layer, and the substrate to form a spacer and to form a trench in the substrate, wherein the spacer is located on a sidewall and a top surface of the patterned hard mask layer and is located on a sidewall of the patterned floating gate material layer;
removing the spacer; and
forming the first isolation structure in the trench.

3. The manufacturing method of the semiconductor structure according to claim 2, further comprising:
in the process of removing the spacer, simultaneously removing a portion of the dielectric material layer located directly below the spacer.

4. The manufacturing method of the semiconductor structure according to claim 2, wherein the first isolation structure is located on the sidewall of the patterned hard mask layer and the sidewall of the patterned floating gate material layer.

5. The manufacturing method of the semiconductor structure according to claim 1, wherein a method of forming the first floating gate layer and the tunneling dielectric layer comprises:
sequentially forming a dielectric material layer, a floating gate material layer, and a hard mask layer on the substrate; and
patterning the hard mask layer, the floating gate material layer, and the dielectric material layer in the memory region to form a patterned hard mask layer, the first floating gate layer, and the tunneling dielectric layer.

6. The manufacturing method of the semiconductor structure according to claim 5, wherein a method of forming the second isolation structure comprises:
patterning the substrate in the memory region to form a trench in the substrate; and
forming the second isolation structure in the trench.

7. The manufacturing method of the semiconductor structure according to claim 5, wherein the second isolation structure is located on a sidewall of the tunneling dielectric layer and a sidewall of the first floating gate layer.

8. The manufacturing method of the semiconductor structure according to claim 5, further comprising:
forming a patterned photoresist layer is in the peripheral region, wherein the patterned photoresist layer covers the first isolation structure;
performing an etch back process on the second isolation structure by using the patterned photoresist layer as a mask to reduce a height of the second isolation structure;
removing the patterned photoresist layer; and
removing the patterned hard mask layer.

9. The manufacturing method of the semiconductor structure according to claim 8, wherein a top surface of the second isolation structure is higher than a bottom surface of the first floating gate layer and lower than a top surface of the first floating gate layer.

10. The manufacturing method of the semiconductor structure according to claim 1, further comprising:
forming a second floating gate layer on the first floating gate layer.

11. The manufacturing method of the semiconductor structure according to claim 10, wherein a width of the second floating gate layer is greater than a width of the first floating gate layer.

12. The manufacturing method of the semiconductor structure according to claim 10, wherein a portion of the second floating gate layer is located on the second isolation structure.

13. The manufacturing method of the semiconductor structure according to claim 10, wherein a method of forming the second floating gate layer comprises:
forming a floating gate material layer on the first floating gate layer; and
patterning the floating gate material layer to form the second floating gate layer and an opening.

14. The manufacturing method of the semiconductor structure according to claim 13, wherein the floating gate material layer is patterned by a lithography process and an etching process.

15. The manufacturing method of the semiconductor structure according to claim 14, wherein the etching process comprises a dry etching process.

16. The manufacturing method of the semiconductor structure according to claim 13, further comprising:
forming a control gate on the second floating gate layer and in the opening; and
forming a dielectric layer between the control gate and the second floating gate layer.

17. The manufacturing method of the semiconductor structure according to claim 1, further comprising:
forming a first gate dielectric layer on the substrate in the peripheral region;
forming a second gate dielectric layer on the substrate in the peripheral region, wherein
the first gate dielectric layer and the second gate dielectric layer are separated from each other, and
a thickness of the first gate dielectric layer is greater than a thickness of the second gate dielectric layer.

18. The manufacturing method of the semiconductor structure according to claim 17, further comprising:
forming a gate material layer on the first gate dielectric layer and the second gate dielectric layer.

19. The manufacturing method of the semiconductor structure according to claim 1, wherein a depth of the first isolation structure located in the substrate is greater than a depth of the second isolation structure located in the substrate.

20. The manufacturing method of the semiconductor structure according to claim 1, wherein a width of the first isolation structure located in the substrate is greater than a width of the second isolation structure located in the substrate.
